(19) United States
(12) Patent Application Publication
(10) Pub. No.: US 2025/0191899 A1
(43) Pub. Date: Jun. 12, 2025

(54) TEMPERATURE CONTROL SYSTEM AND PLASMA PROCESSING SYSTEM

(71) Applicant: Tokyo Electron Limited, Tokyo (JP)

(72) Inventors: Hayato SAKAI, Miyagi (JP); Kazuhiro CHIBA, Miyagi (JP)

(73) Assignee: Tokyo Electron Limited, Tokyo (JP)

(21) Appl. No.: 19/058,027

(22) Filed: Feb. 20, 2025

Related U.S. Application Data
(63) Continuation of application No. PCT/JP2023/030155, filed on Aug. 22, 2023.
(60) Provisional application No. 63/403,119, filed on Sep. 1, 2022.

(51) Int. Cl. H01J 37/32

(52) U.S. Cl. CPC H01J 37/32954; H01J 37/32091; H01J 2237/002

(57) ABSTRACT

The disclosed temperature control system includes a first segment, a second segment, and a connector. The first segment includes a first temperature control circuit and a first case accommodating the first temperature control circuit therein, the first temperature control circuit including a first heat exchanger for exchanging heat with a first temperature-controlled medium. The second segment includes a first tank and a first pump in a first circulation system for circulating the first temperature-controlled medium through a first flow path in a first member of a plasma processing apparatus and includes a second case accommodating the first tank and the first pump therein. The connector is a part of the first circulation system, is disposed between the first segment and the second segment, and is connected between the first pump and the first heat exchanger.

### CROSS-REFERENCE TO RELATED APPLICATIONS

This application is a bypass continuation application of international application No. PCT/JP2023/030155 having an international filing date of Aug. 22, 2023 and designating the United States, the international application being based upon and claiming the benefit of priority from U.S. Application No. 63/403,119, filed on Sep. 1, 2022, the entire contents of each are incorporated herein by reference.

### TECHNICAL FIELD

Exemplary embodiments of the present disclosure relate to a temperature control system and a plasma processing system.

### BACKGROUND

JP2001-44176A described below describes a plasma processing apparatus in which a temperature-controlled medium is circulated by a chiller unit through a flow path in a substrate support that supports a substrate to control a temperature of the substrate.

### CITATION LIST

### Patent Documents

PTL 1: JP2001-44176A

### SUMMARY

The disclosure provides a technique for reducing a size of a unit forming a temperature control system in a plasma processing system.

According to one or more embodiments of the present application, a temperature control system is provided. The temperature control system includes a first segment, a second segment, and a connector. The first segment includes a first temperature control circuit and a first case. The first temperature control circuit includes a first heat exchanger configured to exchange heat with a first temperature-controlled medium. The first case accommodates the first temperature control circuit therein. The second segment includes a first tank, a first pump, and a second case. The first tank and the first pump are provided in a first circulation system configured to circulate the first temperature-controlled medium through a first flow path in a first member of the plasma processing apparatus. The second case accommodates the first tank and the first pump therein. In the first circulation system, the first tank is connected between the first flow path and the first pump, and the first heat exchanger is connected between the first pump and the first flow path. The connector is a part of the first circulation system, is disposed between the first segment and the second segment, and is connected between the first pump and the heat exchanger.

According to one or more embodiments of the present application, a technique for reducing a size of a unit forming a temperature control system in a plasma processing system is provided.

### BRIEF DESCRIPTION OF DRAWINGS

FIG. 1 is a diagram illustrating an example of a configuration of a plasma processing system according to one or more embodiments of the present application.

FIG. 2 is a diagram illustrating an example of a configuration of a capacitively-coupled plasma processing apparatus according to one or more embodiments of the present application.

FIG. 3 is a diagram schematically illustrating a temperature control system according to one or more embodiments of the present application.

FIG. 4 is a diagram schematically illustrating a temperature control system according to one or more embodiments of the present application.

FIG. 5 is a diagram schematically illustrating a temperature control system according to one or more embodiments of the present application.

FIG. 6 is a cross-sectional view illustrating an upper electrode which is an example of a second member in a temperature control system according to one or more embodiments of the present application.

FIG. 7 is a diagram schematically illustrating a temperature control system according to one or more embodiments of the present application.

### DETAILED DESCRIPTION

Hereinafter, various exemplary embodiments, that are usable together, will be described in detail with reference to the drawings. Further, like reference numerals will be given to like or corresponding parts throughout the drawings.

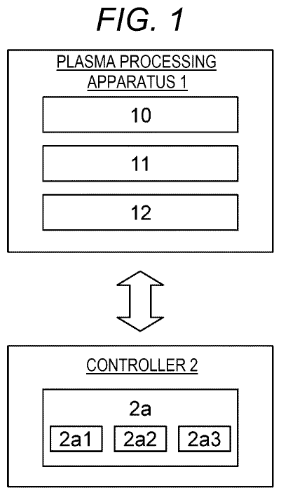

FIG. 1 is a diagram illustrating an example of a configuration of a plasma processing system. In one embodiment, the plasma processing system includes a plasma processing apparatus 1 and a controller 2. The plasma processing system is an example of a substrate processing system, and the plasma processing apparatus 1 is an example of the substrate processing apparatus. The plasma processing apparatus 1 includes a plasma processing chamber 10, a substrate support 11, and a plasma generator 12. The plasma processing chamber 10 has a plasma processing space. The plasma processing chamber 10 has at least one gas supply port via which at least one processing gas is supplied into the plasma processing space, and at least one gas exhaust port via which the gas is exhausted from the plasma processing space. The gas supply port is connected to a gas supplier 20, which will be described later, and the gas exhaust port is connected to an exhaust system 40, which will be described later. The substrate support 11 is disposed in the plasma processing space and has a substrate support surface for supporting a substrate.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave plasma (HWP), surface wave plasma (SWP), or the like. Various types of plasma generators, including an alternating current (AC) plasma generator and a direct current (DC) plasma generator, may be used. In one embodiment, an AC signal (AC power) used by the AC plasma generator has a frequency within a range from 100 kHz to 10 GHz. Accordingly, the AC signal includes a radio frequency (RF) signal and a microwave signal. In one embodiment, the RF signal has a frequency in a range of 100 kHz to 150 MHz.

The controller 2 processes computer-executable instructions for instructing the plasma processing apparatus 1 to execute various steps described in the disclosure. The controller 2 may be configured to control elements of the plasma processing apparatus 1 to execute the various steps described herein. In one embodiment, a portion or the entirety of the controller 2 may be provided in the plasma processing apparatus 1. The controller 2 may include a processor 2a1, a storage 2a2, and a communication interface 2a3. The controller 2 is implemented, for example, by a computer 2a. The processor 2al may be configured to read a program from the storage 2a2 and perform various control operations by executing the read program. The program may be stored in advance in the storage 2a2, or may be acquired via a medium when necessary. The acquired program is stored in the storage 2a2, read from the storage 2a2 by the processor 2a1, and executed thereby. The medium may be any of various storage media readable by the computer 2a, or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASICS.

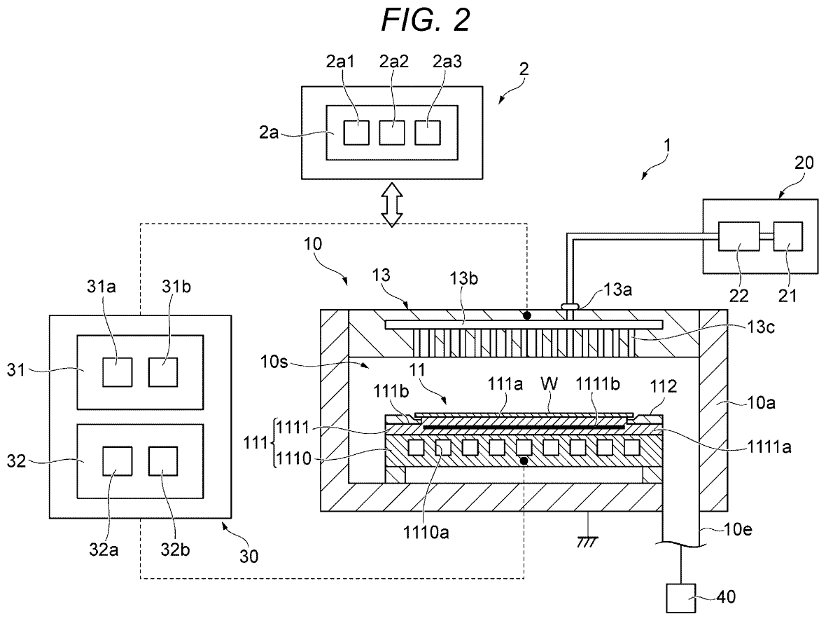

Hereinafter, an example of a configuration of a capacitively-coupled plasma processing apparatus as an example of the plasma processing apparatus 1 will be described. FIG. 2 is a diagram illustrating the example of the configuration of the capacitively-coupled plasma processing apparatus.

The capacitively-coupled plasma processing apparatus 1 includes the plasma processing chamber 10, the gas supplier 20, a power source 30, and the exhaust system 40. The plasma processing apparatus 1 includes the substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 forms at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a, which supports a substrate W, and an annular region 111b, which supports the ring assembly 112. A wafer is an example of the substrate W. The annular region 111b of the main body 111 surrounds the central region 111a of the main body 111 in a plan view. The substrate W is disposed on the central region 111a of the main body 111. The ring assembly 112 is disposed on the annular region 111b of the main body 111 to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a, and an electrostatic electrode 1111b disposed in the ceramic member 1111a. The ceramic member 1111a has the central region 111a. In one embodiment, the ceramic member 1111a also has the annular region 111b. Another member that surrounds the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. At least one RF/DC electrode coupled to an RF power source 31 and/or a DC power source 32, which will be described later, may be disposed in the ceramic member 1111a. In this case, at least one RF/DC electrode functions as the lower electrode. When a bias RF signal and/or DC signal, which will be described later, is supplied to at least one RF/DC electrode, the RF/DC electrode is also referred to as a bias electrode. The conductive member of the base 1110 and at least one RF/DC electrode may function as a plurality of lower electrodes. The electrostatic electrode 1111b may function as the lower electrode. Accordingly, the substrate support 11 includes at least one lower electrode.

The ring assembly 112 includes one or more annular members. In one embodiment, the one or more annular members include one or more edge rings and at least one cover ring. The edge ring is formed of a conductive material or an insulating material, and the cover ring is formed of an insulating material.

The substrate support 11 may include a temperature control module configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid, such as a brine or gas, flows through the flow path 1110a. In one embodiment, the flow path 1110a is formed in the base 1110, and one or more heaters are disposed in the ceramic member 1111a of the electrostatic chuck 1111. The substrate support 11 may include a heat transfer gas supplier configured to supply a heat transfer gas to a gap between a rear surface of the substrate W and the central region 111a.

The shower head 13 is configured to introduce at least one processing gas from the gas supplier 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. The shower head 13 includes at least one upper electrode. The gas introduction unit may include, in addition to the shower head 13, one or more side gas injectors (SGI) that are attached to one or more openings formed in the sidewall 10a.

The gas supplier 20 may include at least one gas source 21 and at least one flow rate controller 22. In one embodiment, the gas supplier 20 is configured to supply at least one processing gas from the respective corresponding gas sources 21 to the shower head 13 via the respective corresponding flow rate controllers 22. The flow rate controller 22 may include, for example, a mass flow controller or a pressure-controlled flow rate controller. Further, the gas supplier 20 may include at least one flow rate modulation device that modulates or pulses a flow rate of at least one processing gas.

The power source 30 includes the RF power source 31 coupled to the plasma processing chamber 10 via at least one impedance matching circuit. The RF power source 31 is configured to supply at least one RF signal (RF power) to at least one lower electrode and/or at least one upper electrode. Accordingly, plasma is formed from at least one processing gas supplied into the plasma processing space 10s. Accordingly, the RF power source 31 may function as at least a part of the plasma generator 12. Supplying the bias RF signal to at least one lower electrode can generate a bias potential in the substrate W to attract an ionic component in the formed plasma to the substrate W.

In one embodiment, the RF power source 31 includes a first RF generator 31a and a second RF generator 31b. The first RF generator 31a is coupled to at least one lower electrode and/or at least one upper electrode via at least one impedance matching circuit, and is configured to generate a source RF signal (source RF power) for plasma generation. In one embodiment, the source RF signal has a frequency within a range from 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate the bias RF signal (bias RF power). A frequency of the bias RF signal may be the same as or different from a frequency of the source RF signal. In one embodiment, the bias RF signal has a frequency lower than the frequency of the source RF signal. In one embodiment, the bias RF signal has a frequency within a range from 100 kHz to 60 MHz. In one embodiment, the second RF generator 31b may be configured to generate a plurality of bias RF signals having different frequencies. The generated one or more bias RF signals are supplied to at least one lower electrode. In various embodiments, at least one of the source RF signal and the bias RF signal may be pulsed.

The power source 30 may include the DC power source 32 coupled to the plasma processing chamber 10. The DC power source 32 includes a first DC generator 32a and a second DC generator 32b. In one embodiment, the first DC generator 32a is connected to at least one lower electrode and configured to generate a first DC signal. The generated first DC signal is applied to the at least one lower electrode. In one embodiment, the second DC generator 32b is connected to at least one upper electrode and configured to generate a second DC signal. The generated second DC signal is applied to the at least one upper electrode.

In various embodiments, the first and second DC signals may be pulsed. In this case, a sequence of voltage pulses is applied to at least one lower electrode and/or at least one upper electrode. The voltage pulses may each have a rectangular, trapezoidal, or triangular pulse waveform or a combination thereof. In one embodiment, a waveform generator that generates the sequence of the voltage pulses from a DC signal is connected between the first DC generator 32a and at least one lower electrode. Accordingly, the first DC generator 32a and the waveform generator form a voltage pulse generator. When the second DC generator 32b and the waveform generator form a voltage pulse generator, the voltage pulse generator is connected to at least one upper electrode. The voltage pulse may have a positive polarity or a negative polarity. The sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected to, for example, a gas exhaust port 10e provided at a bottom portion of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof.

Hereinafter, temperature control systems according to one or more embodiments of the present application that may be adopted in the plasma processing system will be described.

### First Embodiment

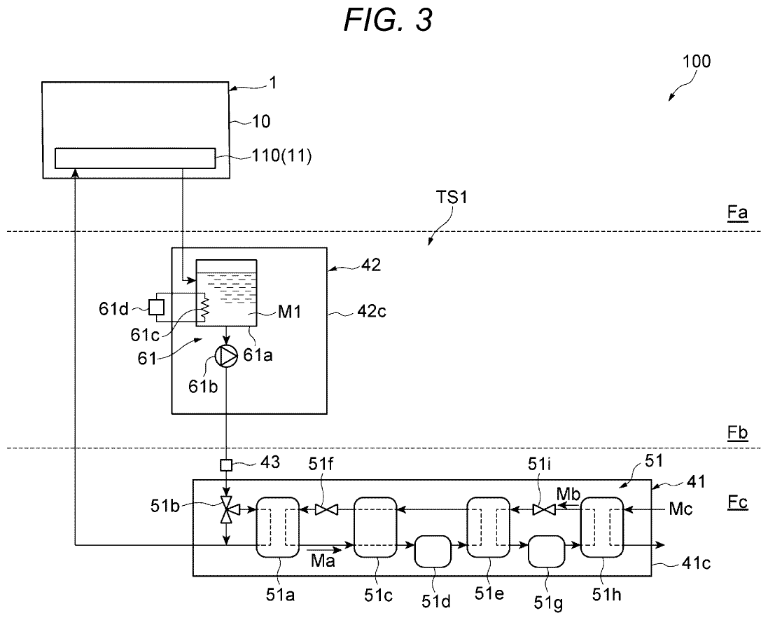

FIG. 3 is a diagram schematically illustrating a temperature control system according to one or more embodiments of the present application. In FIG. 3, arrows indicate flows of a temperature-controlled medium M1 (first temperature-controlled medium) or the like. The temperature-controlled medium M1 may be a coolant such as a brine. FIG. 3 illustrates a configuration of a temperature control system TS1 in a plasma processing system 100. In the plasma processing system 100, the plasma processing apparatus 1 includes a first member 110. The first member 110 may be, for example, the substrate support 11 for supporting the substrate W.

As illustrated in FIG. 3, the temperature control system TS1 includes a first segment 41, a second segment 42, and a connector 43. The first segment 41 includes a temperature control circuit 51 (first temperature control circuit) and a case 41c (first case). The temperature control circuit 51 is configured to adjust a temperature of the temperature-controlled medium M1 to, for example, a first temperature T1. The temperature control circuit 51 may include an apparatus for adjusting the temperature of the temperature-controlled medium M1, and may include, for example, a heat exchanger 51a (first heat exchanger). The temperature control circuit 51 is accommodated in the case 41c. In one embodiment, the temperature control circuit 51 may be a refrigeration circuit. The heat exchanger 51a may be an evaporator.

The second segment 42 includes a circulator 61 (first circulator) and a case 42c (second case). The circulator 61 is a part of a first circulation system. The circulator 61 is accommodated in the case 42c different from the case 41c. The first circulation system is configured to circulate the temperature-controlled medium M1 through a first flow path (for example, the flow path 1110a) in the first member 110. The circulator 61 may include a tank 61a (first tank) in which the temperature-controlled medium M1 is stored, and a pump 61b (first pump) for circulating the temperature-controlled medium M1. In the first circulation system, the tank 61a is connected between one end (outlet) of the first flow path and the pump 61b, and the heat exchanger 51a is connected between a pump 62b and the other end (inlet) of the first flow path. The second segment 42 may further include a heater 61c. The heater 61c is provided in the tank 61a to heat the temperature-controlled medium M1. The heater 61c is connected to a heater power source 61d, and generates heat by the power from the heater power source 61d.

The connector 43 connects the temperature control circuit 51 and the circulator 61 to allow the temperature-controlled medium M1 to flow therebetween. The connector 43 is a part of the first circulation system and is connected between the pump 61b and the heat exchanger 51a. The connector 43 is disposed between the first segment 41 and the second segment 42. The connector 43 may be a joint that connects a pipe extending from the first segment 41 and a pipe extending from the second segment to each other. The connector 43 may connect a pipe extending from the pump 61b and a pipe extending from a three-way valve 51b to be described later to each other.

In one embodiment, the first segment 41 is disposed on a floor Fc. The second segment 42 is disposed on a floor Fb different from the floor Fc. The floor Fc may be a floor below the floor Fb. The floor Fb may be the same floor as, or different from, a floor Fa on which the plasma processing apparatus 1 is disposed. In an example, the floor Fb is a floor between the floor Fc and the floor Fa on which the plasma processing apparatus 1 is disposed.

In one embodiment, the first segment may include, in addition to the heat exchanger 51a, the three-way valve 51b, a recuperator 51c, a compressor 51d, a cascade condenser 51e, an expansion valve 51f, a compressor 51g, a condenser 51h, and an expansion valve 51i.

A first port of the three-way valve 51b is connected to the connector 43 through a pipe. A second port of the three-way valve 51b is connected to an inlet of the heat exchanger 51a for the temperature-controlled medium M1. A pipe extending from a third port of the three-way valve 51b joins a pipe that connects an outlet of the heat exchanger 51a for the temperature-controlled medium M1 and an inlet of the first flow path to each other.

The heat exchanger 51a is configured to adjust the temperature of the temperature-controlled medium M1 by heat exchange between the temperature-controlled medium M1 and a temperature-controlled medium Ma. The heat exchanger 51a, the recuperator 51c, the compressor 51d, the cascade condenser 51e, and the expansion valve 51f form a circuit for circulating the temperature-controlled medium Ma through the heat exchanger 51a. An outlet of the heat exchanger 51a for the temperature-controlled medium Ma is connected to a first inlet of the recuperator 51c. A first outlet of the recuperator 51c is connected to an inlet of the cascade condenser 51e for the temperature-controlled medium Ma via the compressor 51d. An outlet of the cascade condenser 51e for the temperature-controlled medium Ma is connected to a second inlet of the recuperator 51c. A second outlet of the recuperator 51c is connected to an inlet of the heat exchanger 51a for the temperature-controlled medium Ma via the expansion valve 51f.

The cascade condenser 51e is configured to adjust the temperature of the temperature-controlled medium Ma by heat exchange between the temperature-controlled medium Ma and a temperature-controlled medium Mb. The cascade condenser 51e, the compressor 51g, the condenser 51h, and the expansion valve 51i form a circuit for circulating the temperature-controlled medium Mb through the cascade condenser 51e. An outlet of the cascade condenser 51e for the temperature-controlled medium Mb is connected to an inlet of the condenser 51h for the temperature-controlled medium Mb via the compressor 51g. An outlet of the condenser 51h for the temperature-controlled medium Mb is connected to an inlet of the cascade condenser 51e for the temperature-controlled medium Mb via the expansion valve 51i. The condenser 51h is configured to adjust a temperature of the temperature-controlled medium Mb by heat exchange between the temperature-controlled medium Mb and a temperature-controlled medium Mc.

In the temperature control system TS1, after the temperature of the temperature-controlled medium M1 is adjusted to, for example, the first temperature T1 by the temperature control circuit 51 of the first segment 41, the temperature-controlled medium M1 is supplied to the first flow path (for example, the flow path 1110a) in the first member 110. When the temperature-controlled medium M1 cools the first member 110, the temperature of the temperature-controlled medium M1 increases from the first temperature T1 by ΔT1. The temperature-controlled medium M1 whose temperature has increased by ΔT1 is returned to the temperature control circuit 51 by the circulator 61 of the second segment 42. Then, after the temperature of the temperature-controlled medium M1 is adjusted to the first temperature T1 by the temperature control circuit 51, the temperature-controlled medium M1 is supplied again to the first flow path (for example, the flow path 1110a) in the first member 110.

In the temperature control system TS1, the second segment 42 forming a part of the first circulation system is separated from the first segment 41 that includes the temperature control circuit 51. Accordingly, it is possible to reduce a size of a unit forming the temperature control system TS1. In the temperature control system TS1, the second segment 42 can be disposed on the floor Fb different from the floor Fc on which the first segment 41 is disposed. Accordingly, it is possible to reduce an arrangement area of the unit of the temperature control system TS1 on the floor Fc. In an example, the arrangement area of the temperature control system TS1 on the floor Fc can be reduced to 60% or less, 50% or less, or 40% or less of an arrangement area of a temperature control system in the related art.

Since the temperature control system TS1 is divided into the first segment 41 and the second segment 42, a degree of freedom of a design thereof is high. Since the second segment 42 can be disposed immediately below the plasma processing apparatus 1, the temperature control system TS1 can shorten a hose (pipe) that connects the second segment 42 and the plasma processing apparatus 1, and is also excellent in temperature control efficiency. Further, when an abnormality occurs in either the first segment 41 or the second segment 42, only the segment in which the abnormality has occurred can be replaced. Therefore, recovery work during the abnormality is shortened.

### Second Embodiment

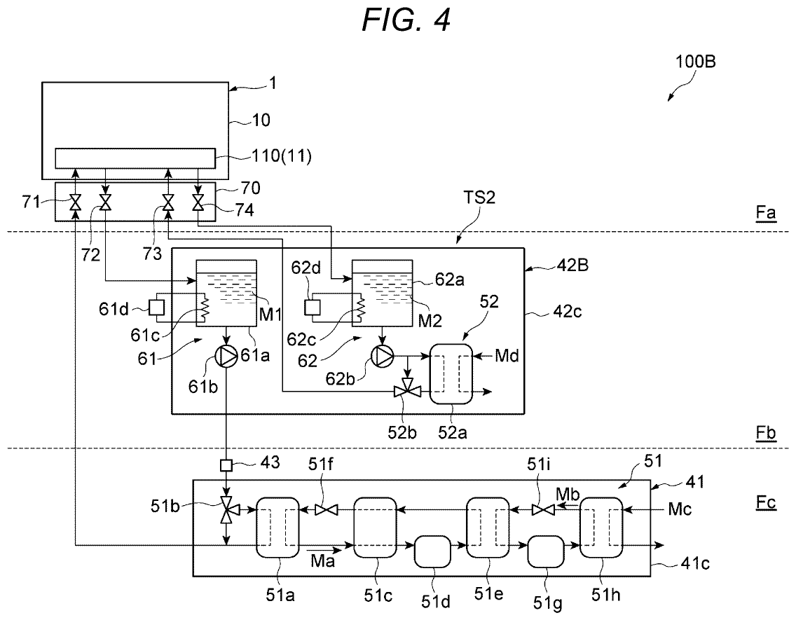

Next, one or more embodiments of the present application will be described. FIG. 4 is a diagram schematically illustrating a temperature control system according to according to one or more embodiments of the present application. In FIG. 4, arrows indicate flows of the temperature-controlled medium M1, a temperature-controlled medium M2 (a second temperature-controlled medium), or the like. The temperature-controlled medium M2 may be a coolant such as a brine. The temperature-controlled medium M2 may be the same coolant as the temperature-controlled medium M1. FIG. 4 illustrates a configuration of a temperature control system TS2 in a plasma processing system 100B. In the plasma processing system 100B, the plasma processing apparatus 1 includes the first member 110. The first member 110 may be, for example, the substrate support 11 for supporting the substrate W. Hereinafter, the plasma processing system 100B will be described from the viewpoint of differences from the plasma processing system 100.

The temperature control system TS2 includes the first segment 41, a second segment 42B, and the connector 43. The first segment 41 and the connector 43 are similar to the first segment 41 and the connector 43 of the temperature control system TS1, respectively.

The temperature control system TS2 may further include a switcher 70. The switcher 70 may be configured to switch, between the temperature-controlled medium M1 and the temperature-controlled medium M2, a temperature-controlled medium circulating through the first flow path (for example, the flow path 1110a). In one embodiment, the switcher 70 may include valves 71 to 74. Each of the valves 71 to 74 is, for example, an opening/closing valve. The valve 71 is connected between the outlet of the heat exchanger 51a for the temperature-controlled medium M1 and the inlet of the first flow path. The valve 72 is connected between an outlet of the first flow path and the tank 61a.

In the temperature control system TS2, the second segment 42B is different from the second segment 42 of the temperature control system TS1 in that the second segment 42B further includes a temperature control circuit 52 (second temperature control circuit) and a circulator 62 (second circulator). In the temperature control system TS2, the second segment 42B may further include a three-way valve 52b. The three-way valve 52b is accommodated in the case 42c.

The temperature control circuit 52 is configured to adjust a temperature of the temperature-controlled medium M2 to, for example, a second temperature T2. The temperature control circuit 52 may include an apparatus for adjusting the temperature of the temperature-controlled medium M2, and may include, for example, a heat exchanger 52a (second heat exchanger). The second temperature T2 may be higher than the first temperature T1. The heat exchanger 52a is configured to adjust the temperature of the temperature-controlled medium M2 by heat exchange between the temperature-controlled medium M2 and a temperature-controlled medium Md. In one embodiment, the heat exchanger 52a may be a condenser.

The circulator 62 is a part of a second circulation system. The circulator 62, together with the circulator 61 and the temperature control circuit 52, is accommodated in the case 42c. The second circulation system is configured to circulate the temperature-controlled medium M2, which is adjusted to the second temperature T2, through the first flow path (for example, the flow path 1110a). The circulator 62 may include a tank 62a (second tank) in which the temperature-controlled medium M2 is stored, and the pump 62b (second pump) for circulating the temperature-controlled medium M2.

In the second circulation system, the tank 62a is connected between the outlet of the first flow path and the pump 62b, and the heat exchanger 52a is connected between the pump 62b and the inlet of the first flow path. An outlet of the heat exchanger 52a for the temperature-controlled medium M2 may be connected to the inlet of the first flow path via the valve 73. The outlet of the first flow path may be connected to the tank 62a via the valve 74. In one embodiment, the pump 62b may be connected to an inlet of the heat exchanger 52a for the temperature-controlled medium M2 and a first port of the three-way valve 52b. The outlet of the heat exchanger 52a for the temperature-controlled medium M2 may be connected to a second port of the three-way valve 52b. A third port of the three-way valve 52b may be connected to the inlet of the first flow path.

The second segment 42B may further include a heater 62c. The heater 62c is provided in the tank 62a to heat the temperature-controlled medium M2. The heater 62c is connected to a heater power source 62d, and generates heat by the power from the heater power source 62d.

In the temperature control system TS2, after the temperature of the temperature-controlled medium M2 is adjusted to, for example, the second temperature T2 by the temperature control circuit 52 of the second segment 42B, the temperature-controlled medium M2 is supplied to the first flow path (for example, the flow path 1110a) in the first member 110. When the temperature-controlled medium M2 cools the first member 110, the temperature of the temperature-controlled medium M2 increases from the second temperature T2 by ΔT2. The temperature-controlled medium M2 whose temperature has increased by ΔT2 is returned to the temperature control circuit 52 by the circulator 62 of the second segment 42B. Then, after the temperature of the temperature-controlled medium M2 is adjusted to the second temperature T2 by the temperature control circuit 52, the temperature-controlled medium M2 is supplied again to the first flow path (for example, the flow path 1110a) in the first member 110.

The switcher 70 may be configured to switch the temperature-controlled medium, which is supplied to the first flow path, from the temperature-controlled medium M1 to the temperature-controlled medium M2 or from the temperature-controlled medium M2 to the temperature-controlled medium M1. Alternatively, the switcher 70 may be configured to supply, to the first flow path, a temperature-controlled medium which is acquired by mixing the temperature-controlled medium M1 and the temperature-controlled medium M2 at a designated ratio. In this case, the temperature-controlled medium M1 and the temperature-controlled medium M2 may be the same temperature-controlled medium.

In the temperature control system TS2, the second segment 42B is separated from the first segment 41, similarly to the temperature control system TS1. Accordingly, it is possible to reduce a size of a unit forming the temperature control system TS2. Similar to the temperature control system TS1, the temperature control system TS2 can dispose the second segment 42B on the floor Fb different from the floor Fc on which the first segment 41 is disposed. Accordingly, similar to the temperature control system TS1, the temperature control system TS2 can reduce an arrangement area of the unit of the temperature control system TS2 on the floor Fc. Similar to the temperature control system TS1, the temperature control system TS2 can improve a degree of freedom of a design, improve temperature control efficiency, and shorten recovery work during an abnormality.

### Third Embodiment

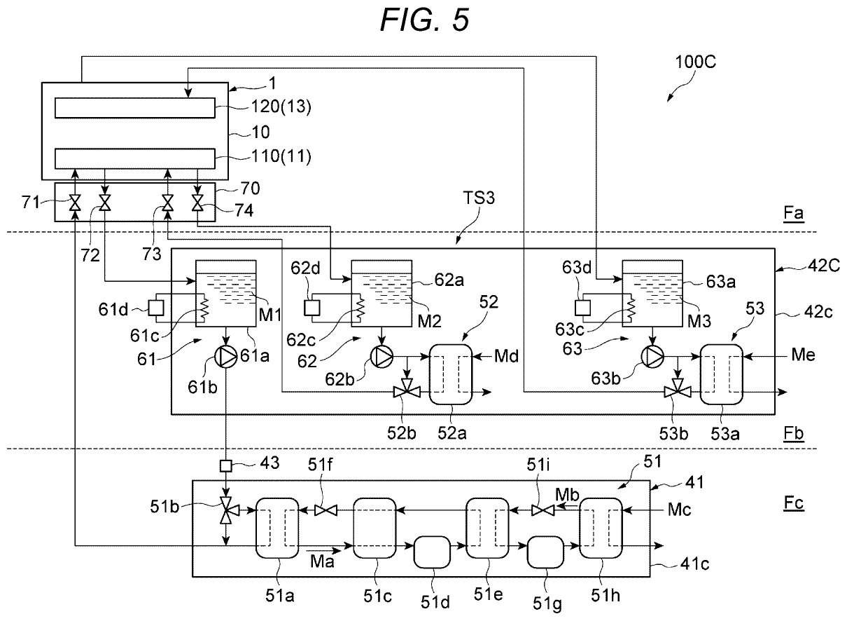

Next, one or more embodiments of the present application will be described. FIG. 5 is a diagram schematically illustrating a temperature control system according to one or more embodiments of the present application. In FIG. 5, arrows indicate flows of the temperature-controlled medium M1, the temperature-controlled medium M2, a temperature-controlled medium M3 (a third temperature-controlled medium), or the like. The temperature-controlled medium M3 may be a coolant such as a brine. The temperature-controlled medium M3 may be the same coolant as the temperature-controlled medium M1 or the temperature-controlled medium M2.

FIG. 5 illustrates a configuration of a temperature control system TS3 in a plasma processing system 100C. In the plasma processing system 100C, the plasma processing apparatus 1 includes the first member 110 and a second member 120. The first member 110 may be, for example, the substrate support 11 for supporting the substrate W. The second member 120 may be an upper electrode of the plasma processing apparatus 1. Hereinafter, the plasma processing system 100C will be described from the viewpoint of differences from the plasma processing system 100B.

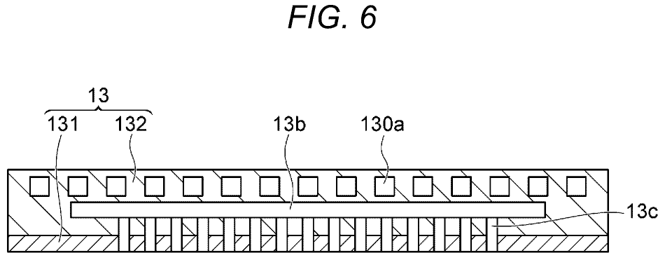

FIG. 6 is a cross-sectional view illustrating an upper electrode which is an example of the second member in a temperature control system according to one or more embodiments of the present application. As illustrated in FIG. 6, the second member 120 may be an upper electrode provided in the shower head 13. The upper electrode has a flow path 130a therein. In one embodiment, the flow path 130a is a second flow path in the second member 120. The upper electrode may include a ceiling plate 131 and a support 132. The ceiling plate 131 defines the plasma processing space 10s from above. The support 132 is provided on the ceiling plate 131. The support 132 has the flow path 130a and at least one gas diffusion chamber 13b therein. The ceiling plate 131 and the support 132 have a plurality of gas introduction ports 13c. The flow path 130a may be provided in the support 132.

As illustrated in FIG. 5, the temperature control system TS3 includes the first segment 41, a second segment 42C, and the connector 43. The first segment 41 and the connector 43 are similar to the first segment 41 and the connector 43 of the temperature control system TS2, respectively.

In the temperature control system TS3, the second segment 42C is different from the second segment 42B of the temperature control system TS2 in that the second segment 42C further includes a temperature control circuit 53 (third temperature control circuit) and a circulator 63 (third circulator). In the temperature control system TS3, the second segment 42C may further include a three-way valve 53b. The three-way valve 53b is accommodated in the case 42c.

The temperature control circuit 53 may include an apparatus for adjusting a temperature of the temperature-controlled medium M3, and may include, for example, a heat exchanger 53a (third heat exchanger). The heat exchanger 53a is configured to adjust the temperature of the temperature-controlled medium M3 by heat exchange between the temperature-controlled medium M3 and a temperature-controlled medium Me. In one embodiment, the heat exchanger 53a may be a condenser.

The circulator 63 is a part of a third circulation system. The circulator 63, together with the circulator 61, the temperature control circuit 52, the circulator 62, and the temperature control circuit 53, is accommodated in the case 42c. The third circulation system is configured to circulate the temperature-controlled medium M3, which is adjusted to a third temperature T3, through the second flow path (for example, the flow path 130a) in the second member 120 different from the first member 110. The circulator 63 may include a tank 63a (third tank) in which the temperature-controlled medium M3 is stored, and a pump 63b (third pump) for circulating the temperature-controlled medium M3.

In the third circulation system, the tank 63a is connected between an outlet of the second flow path and the pump 63b, and the heat exchanger 53a is connected between the pump 63b and an inlet of the second flow path. An outlet of the heat exchanger 53a for the temperature-controlled medium M3 is connected to the inlet of the second flow path. The outlet of the second flow path is connected to the tank 63a. In one embodiment, the pump 63b may be connected to an inlet of the heat exchanger 53a for the temperature-controlled medium M3 and a first port of the three-way valve 53b. The outlet of the heat exchanger 53a for the temperature-controlled medium M3 may be connected to a second port of the three-way valve 53b. A third port of the three-way valve 53b may be connected to the inlet of the second flow path.

The second segment 42C may further include a heater 63c. The heater 63c is provided in the tank 63a to heat the temperature-controlled medium M3. The heater 63c is connected to a heater power source 63d, and generates heat by the power from the heater power source 63d.

In the temperature control system TS3, after the temperature of the temperature-controlled medium M3 is adjusted to, for example, the third temperature T3 by the temperature control circuit 53 of the second segment 42C, the temperature-controlled medium M3 is supplied to the flow path (for example, the flow path 130a) in the second member 120. When the temperature-controlled medium M3 cools the second member 120, the temperature of the temperature-controlled medium M3 increases from the third temperature T3 by ΔT3. The temperature-controlled medium M3 whose temperature has increased by ΔT3 is returned to the temperature control circuit 53 by the circulator 63 of the second segment 42C. Then, after the temperature of the temperature-controlled medium M3 is adjusted to the third temperature T3 by the temperature control circuit 53, the temperature-controlled medium M3 is supplied again to the second flow path (for example, the flow path 130a) in the second member 120.

In the temperature control system TS3, the second segment 42C is separated from the first segment 41, similarly to the temperature control system TS1 and the temperature control system TS2. Accordingly, it is possible to reduce a size of a unit forming the temperature control system TS3. Similar to the temperature control system TS1 and the temperature control system TS2, the temperature control system TS3 can dispose the second segment 42C on the floor Fb different from the floor Fc on which the first segment 41 is disposed. Accordingly, similar to the temperature control system TS1 and the temperature control system TS2, the temperature control system TS3 can reduce an arrangement area of the unit of the temperature control system TS3 on the floor Fc. Similar to the temperature control system TS1 and the temperature control system TS2, the temperature control system TS3 can improve a degree of freedom of a design, improve temperature control efficiency, and shorten recovery work during an abnormality.

### Fourth Embodiment

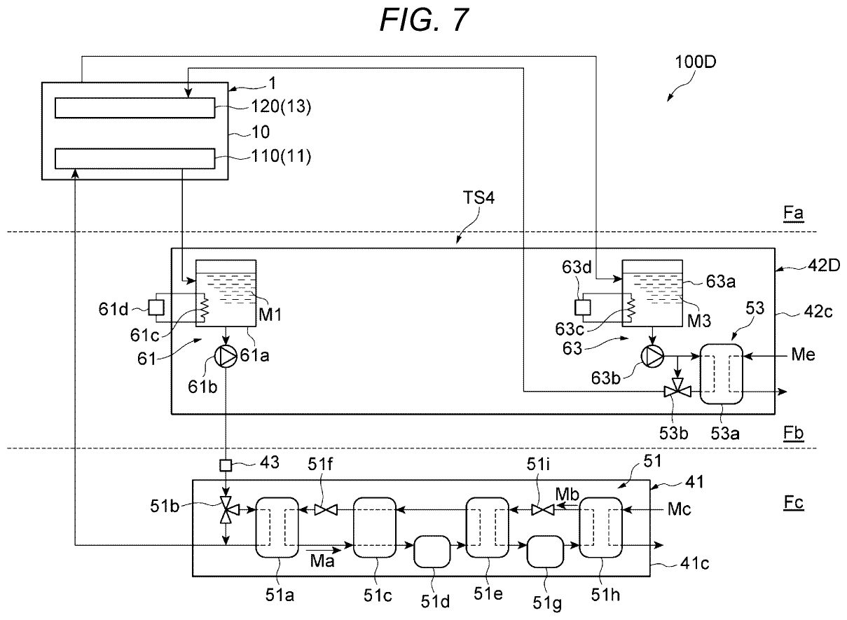

Next, one or more embodiments of the present application will be described. FIG. 7 is a diagram schematically illustrating a temperature control system according to one or more embodiments of the present application. FIG. 7 illustrates a configuration of a temperature control system TS4 in a plasma processing system 100D. Hereinafter, the plasma processing system 100D will be described from the viewpoint of differences from the plasma processing system 100C.

A second segment 42D of the temperature control system TS4 is different from the second segment 42C in that the second segment 42D does not include the temperature control circuit 52 and the circulator 62. The plasma processing system 100D does not include the switcher 70. The temperature control circuit 51 and the circulator 61 of the temperature control system TS4 are connected to the first flow path, similarly to the temperature control circuit 51 and the circulator 61 of the temperature control system TS1. Other components of the temperature control system TS4 are similar to the corresponding components of the temperature control system TS3.

In the temperature control system TS4, the second segment 42D also is separated from the first segment 41. Accordingly, it is possible to reduce a size of a unit forming the temperature control system TS4. In the temperature control system TS4, the second segment 42D can also be disposed on the floor Fb different from the floor Fc on which the first segment 41 is disposed. Accordingly, in the temperature control system TS4, it is also possible to reduce an arrangement area of the unit of the temperature control system TS4 on the floor Fc. The temperature control system TS4 can also improve a degree of freedom of a design, improve temperature control efficiency, and shorten recovery work during an abnormality.

Although various exemplary embodiments have been described above, various additions, omissions, substitutions, and changes may be made without being limited to the exemplary embodiments described above. In addition, other embodiments may be formed by combining elements in different embodiments.

Hereinafter, various exemplary embodiments included in the disclosure will be described in the following [E1] to [E18].

### [E1]

A temperature control system including:
a first segment that includes a first temperature control circuit and a first case accommodating the first temperature control circuit therein, the first temperature control circuit including a first heat exchanger configured to exchange heat with a first temperature-controlled medium;
a second segment that includes a first tank and a first pump in a first circulation system configured to circulate the first temperature-controlled medium through a first flow path in a first member of a plasma processing apparatus and includes a second case accommodating the first tank and the first pump therein, in the first circulation system, the first tank being connected between the first flow path and the first pump, and the first heat exchanger being connected between the first pump and the first flow path; and
a connector that is a part of the first circulation system, is disposed between the first segment and the second segment, and is connected between the first pump and the first heat exchanger.

### [E2]

The temperature control system according to E1, in which
the first temperature control circuit is a refrigeration circuit including an evaporator that is the first heat exchanger.

### [E3]

The temperature control system according to E1 or E2, in which
the second segment further includes
   a second heat exchanger configured to exchange heat with a second temperature-controlled medium, and
   a second tank and a second pump in a second circulation system that includes the second heat exchanger and is configured to circulate the second temperature-controlled medium through the first flow path,
the second tank is connected between the first flow path and the second pump, and the second heat exchanger is connected between the second pump and the first flow path,
the second heat exchanger, the second tank, and the second pump are accommodated in the second case, and
the temperature control system further includes a switcher that selectively connects the first circulation system and the second circulation system to the first flow path.

### [E4]

The temperature control system according to E3, in which
the second heat exchanger is a condenser.

### [E5]

The temperature control system according to E3 or E4, in which
the second segment further includes
   a third heat exchanger configured to exchange heat with a third temperature-controlled medium, and
   a third tank and a third pump in a third circulation system that includes the third heat exchanger and is configured to circulate the third temperature-controlled medium through a second flow path in a second member of the plasma processing apparatus,
the third tank is connected between the second flow path and the third pump, and the third heat exchanger is connected between the third pump and the second flow path, and
the third heat exchanger, the third tank, and the third pump are accommodated in the second case.

### [E6]

The temperature control system according to E1 or E2, in which
the second segment further includes
   a second heat exchanger configured to exchange heat with a second temperature-controlled medium, and
   a second tank and a second pump in a second circulation system that includes the second heat exchanger and is configured to circulate the second temperature-controlled medium through a second flow path in a second member of the plasma processing apparatus,
the second tank is connected between the second flow path and the second pump, and the second heat exchanger is connected between the second pump and the second flow path, and
the second heat exchanger, the second tank, and the second pump are accommodated in the second case.

### [E7]

The temperature control system according to E5 or E6, in which
the second member is an upper electrode of a capacitively-coupled plasma processing apparatus.

### [E8]

The temperature control system according to any one of E1 to E7, in which
the first member is a substrate support of the plasma processing apparatus.

### [E9]

The temperature control system according to any one of E1 to E8, in which
the first segment is disposed on a floor below a floor on which the second segment is disposed.

### [E10]

A plasma processing system including:
a plasma processing apparatus; and
a temperature control system, in which
the plasma processing apparatus includes
   a chamber, and
   a first member providing a first flow path therein, and
the temperature control system includes
   a first segment that includes a first temperature control circuit and a first case accommodating the first temperature control circuit therein, the first temperature control circuit including a first heat exchanger configured to exchange heat with a first temperature-controlled medium,
   a second segment that includes a first tank and a first pump in a first circulation system configured to circulate the first temperature-controlled medium through the first flow path and includes a second case accommodating the first tank and the first pump therein, in the first circulation system, the first tank being connected between the first flow path and the first pump, and the first heat exchanger being connected between the first pump and the first flow path, and
   a connector that is a part of the first circulation system, is disposed between the first segment and the second segment, and is connected between the first pump and the first heat exchanger.

### [E11]

The plasma processing system according to E10, in which
the first temperature control circuit is a refrigeration circuit including an evaporator that is the first heat exchanger.

### [E12]

The plasma processing system according to E10 or E11, in which
the second segment further includes
   a second heat exchanger configured to exchange heat with a second temperature-controlled medium, and
   a second tank and a second pump in a second circulation system that includes the second heat exchanger and is configured to circulate the second temperature-controlled medium through the first flow path,
the second tank is connected between the first flow path and the second pump, and the second heat exchanger is connected between the second pump and the first flow path,
the second heat exchanger, the second tank, and the second pump are accommodated in the second case, and
the temperature control system further includes a switcher that selectively connects the first circulation system and the second circulation system to the first flow path.

### [E13]

The plasma processing system according to E12, in which
the second heat exchanger is a condenser.

### [E14]

The plasma processing system according to E12 or E13, in which
the second segment further includes
   a third heat exchanger configured to exchange heat with a third temperature-controlled medium, and
   a third tank and a third pump in a third circulation system that includes the third heat exchanger and is configured to circulate the third temperature-controlled medium through a second flow path in a second member of the plasma processing apparatus,
the third tank is connected between the second flow path and the third pump, and the third heat exchanger is connected between the third pump and the second flow path, and
the third heat exchanger, the third tank, and the third pump are accommodated in the second case.

### [E15]

The plasma processing system according to E10 or E11, in which
the second segment further includes
   a second heat exchanger configured to exchange heat with a second temperature-controlled medium, and
   a second tank and a second pump in a second circulation system that includes the second heat exchanger and is configured to circulate the second temperature-controlled medium through a second flow path in a second member of the plasma processing apparatus,
the second tank is connected between the second flow path and the second pump, and the second heat exchanger is connected between the second pump and the second flow path, and
the second heat exchanger, the second tank, and the second pump are accommodated in the second case.

### [E16]

The plasma processing system according to E14 or E15, in which
the plasma processing apparatus is a capacitively-coupled plasma processing apparatus, and
the second member is an upper electrode of the plasma processing apparatus.

### [E17]

The plasma processing system according to any one of E10 to E16, in which
the first member is a substrate support of the plasma processing apparatus.

### [E18]

The plasma processing system according to any one of E10 to E17, in which
the first segment is disposed on a floor below a floor on which the second segment is disposed.

From the foregoing, it will be appreciated that various embodiments of the disclosure have been described herein for purposes of illustration, and that various modifications may be made without departing from the scope and spirit of the disclosure. Therefore, the various embodiments disclosed herein are not intended to be limiting, with the true scope and spirit being indicated by the following claims.

1. A temperature control system comprising:
a first segment including a first temperature control circuit and a first case accommodating the first temperature control circuit, the first temperature control circuit including a first heat exchanger configured to exchange heat with a first temperature-controlled medium;
a second segment including a first tank and a first pump in a first circulation system that is configured to circulate the first temperature-controlled medium through a first flow path in a first member of a plasma processing apparatus and the second segment includes a second case accommodating the first tank and the first pump, in the first circulation system, the first tank being connected between the first flow path and the first pump, and the first heat exchanger being connected between the first pump and the first flow path; and
a connector that is a part of the first circulation system, the connector being disposed between the first segment and the second segment, and the connector being connected between the first pump and the first heat exchanger.

2. The temperature control system according to claim 1, wherein
the first temperature control circuit is a refrigeration circuit, and
the first heat exchanger is an evaporator.

3. The temperature control system according to claim 1, wherein
the second segment further includes:
a second heat exchanger configured to exchange heat with a second temperature-controlled medium, and
a second tank and a second pump in a second circulation system including the second heat exchanger and the second circulation system is configured to circulate the second temperature-controlled medium through the first flow path,
the second tank is connected between the first flow path and the second pump, and the second heat exchanger is connected between the second pump and the first flow path,
the second heat exchanger, the second tank, and the second pump are accommodated in the second case, and
the temperature control system further includes a switcher that selectively connects the first circulation system and the second circulation system to the first flow path.

4. The temperature control system according to claim 3, wherein
the second heat exchanger is a condenser.

5. The temperature control system according to claim 3, wherein
the second segment further includes:
a third heat exchanger configured to exchange heat with a third temperature-controlled medium, and
a third tank and a third pump in a third circulation system including the third heat exchanger and the third pump is configured to circulate the third temperature-controlled medium through a second flow path in a second member of the plasma processing apparatus,
the third tank is connected between the second flow path and the third pump, and the third heat exchanger is connected between the third pump and the second flow path, and
the third heat exchanger, the third tank, and the third pump are accommodated in the second case.

6. The temperature control system according to claim 1, wherein
the second segment further includes:
a second heat exchanger configured to exchange heat with a second temperature-controlled medium, and
a second tank and a second pump in a second circulation system including the second heat exchanger and the second circulation system is configured to circulate the second temperature-controlled medium through a second flow path in a second member of the plasma processing apparatus,
the second tank is connected between the second flow path and the second pump, and the second heat exchanger is connected between the second pump and the second flow path, and
the second heat exchanger, the second tank, and the second pump are accommodated in the second case.

7. The temperature control system according to claim 5, wherein
the second member is an upper electrode of a capacitively-coupled plasma processing apparatus.

8. The temperature control system according to claim 1, wherein
the first member is a substrate support of the plasma processing apparatus.

9. The temperature control system according to claim 1, wherein
the first segment is disposed below a floor on which the second segment is disposed.

10. A plasma processing system comprising:
a plasma processing apparatus; and
a temperature control system, wherein
the plasma processing apparatus includes:
a chamber; and
a first member providing a first flow path therein, and
the temperature control system includes:
a first segment including a first temperature control circuit and a first case accommodating the first temperature control circuit, the first temperature control circuit including a first heat exchanger configured to exchange heat with a first temperature-controlled medium,
a second segment including a first tank and a first pump in a first circulation system that is configured to circulate the first temperature-controlled medium through the first flow path and the second segment includes a second case accommodating the first tank and the first pump therein, in the first circulation system, the first tank being connected between the first flow path and the first pump, and the first heat exchanger being connected between the first pump and the first flow path;
and
a connector that is a part of the first circulation system, the connector being disposed between the first segment and the second segment, and the connector being connected between the first pump and the first heat exchanger.

11. The plasma processing system according to claim 10, wherein
the first temperature control circuit is a refrigeration circuit, and
the first heat exchanger is an evaporator.

12. The plasma processing system according to claim 10, wherein
the second segment further includes:
a second heat exchanger configured to exchange heat with a second temperature-controlled medium; and
a second tank and a second pump in a second circulation system including the second heat exchanger and the second circulation system is configured to circulate the second temperature-controlled medium through the first flow path,
the second tank is connected between the first flow path and the second pump, and the second heat exchanger is connected between the second pump and the first flow path,
the second heat exchanger, the second tank, and the second pump are accommodated in the second case, and
the temperature control system further includes a switcher that selectively connects the first circulation system and the second circulation system to the first flow path.

13. The plasma processing system according to claim 12, wherein
the second heat exchanger is a condenser.

14. The plasma processing system according to claim 12, wherein
the second segment further includes:
a third heat exchanger configured to exchange heat with a third temperature-controlled medium, and
a third tank and a third pump in a third circulation system including the third heat exchanger and the third circulation system is configured to circulate the third temperature-controlled medium through a second flow path in a second member of the plasma processing apparatus,
the third tank is connected between the second flow path and the third pump, and the third heat exchanger is connected between the third pump and the second flow path, and
the third heat exchanger, the third tank, and the third pump are accommodated in the second case.

15. The plasma processing system according to claim 10, wherein
the second segment further includes:
a second heat exchanger configured to exchange heat with a second temperature-controlled medium, and
a second tank and a second pump in a second circulation system including the second heat exchanger and the second circulation system is configured to circulate the second temperature-controlled medium through a second flow path in a second member of the plasma processing apparatus,
the second tank is connected between the second flow path and the second pump, and the second heat exchanger is connected between the second pump and the second flow path, and
the second heat exchanger, the second tank, and the second pump are accommodated in the second case.

16. The plasma processing system according to claim 14, wherein
the plasma processing apparatus is a capacitively-coupled plasma processing apparatus, and
the second member is an upper electrode of the plasma processing apparatus.

17. The plasma processing system according to claim 10, wherein
the first member is a substrate support of the plasma processing apparatus.

18. The plasma processing system according to claim 10, wherein
the first segment is disposed below a floor on which the second segment is disposed.

19. The plasma processing system according to claim 12, wherein
the first member is a substrate support of the plasma processing apparatus.

20. The plasma processing system according to claim 12, wherein
the first segment is disposed below a floor on which the second segment is disposed.
